(19) United States
(12) Patent Application Publication
(10) Pub. No.: US 2025/0317090 A1
(43) Pub. Date: Oct. 9, 2025

(54) CURVED SOLAR PANEL, PHOTOVOLTAIC ARRAY, AND SOLAR ENERGY SYSTEM

(71) Applicant: SHENZHEN HELLO TECH ENERGY CO., LTD, Shenzhen (CN)

(72) Inventors: Minhuan ZHANG, Shenzhen (CN); Zhongwei SUN, Shenzhen (CN); Huajun YU, Shenzhen (CN); Yanjun ZHU, Shenzhen (CN)

(21) Appl. No.: 19/243,748

(22) Filed: Jun. 20, 2025

Related U.S. Application Data
(63) Continuation of application No. PCT/CN2024/142360, filed on Dec. 25, 2024.

(30) Foreign Application Priority Data
Jan. 19, 2024 (CN) 202420143851.0

(51) Int. Cl. H02S 20/23; H02S 10/20; H02S 40/30

(52) U.S. Cl. CPC H02S 20/23; H02S 10/20; H02S 40/30

(57) ABSTRACT

Provided are a curved solar panel, a photovoltaic array, and a solar energy system. The curved solar panel includes a crest portion and a trough portion sequentially connected in a first direction. The curved solar panel further includes a power generation area provided with a power generation layer; and a first non-power generation area and a second non-power generation area located at two opposite sides of the power generation area in the first direction, respectively. An upper part of the first non-power generation area overlaps with the second non-power generation area of an adjacent curved solar panel. A width of the first non-power generation area in the first direction is defined as X1, a width of the second non-power generation area in the first direction is defined as X2, and a thickness of the curved solar panel is defined as W, where X1, X2, and W satisfy: X1≥X2+W.

### CROSS-REFERENCE TO RELATED APPLICATION

This application is a continuation of International Application No. PCT/CN2024/142360, filed on Dec. 25, 2024, which claims priority to and benefits of Chinese patent application No. 202420143851.0, filed with China National Intellectual Property Administration on Jan. 19, 2024, the entire content of which incorporated herein by reference.

### FIELD

The present disclosure relates to the field of photovoltaic technologies, and more particularly, to a curved solar panel, a photovoltaic array, and a solar energy system.

### BACKGROUND

In existing solar energy systems using curved solar panels, when the curved solar panels are mounted, a power generation area of the lower curved solar panel is prone to be locally blocked, which reduces the power generation efficiency of the locally blocked curved solar panel, leading to a decrease in the overall power generation efficiency of an entire solar energy system due to current limiting.

### SUMMARY

Embodiments of the present disclosure provide a curved solar panel, a photovoltaic array, and a solar energy system to solve at least one of the above technical problems.

A first aspect of the present disclosure provides a curved solar panel. The curved solar panel includes a crest portion and a trough portion that are sequentially connected in a first direction. The curved solar panel further includes a power generation area provided with a power generation layer, a first non-power generation area and a second non-power generation area. The first non-power generation area and the second non-power generation area are located at two opposite sides of the power generation area in the first direction, respectively. An upper part of the first non-power generation area is configured to overlap with the second non-power generation area of an adjacent curved solar panel. A width of the first non-power generation area in the first direction is defined as X1. A width of the second non-power generation area in the first direction is defined as X2. A thickness of the curved solar panel is defined as W, where X1, X2, and W satisfy: X1≥X2+W.

When the curved solar panel in the first aspect of the present disclosure is mounted in the first direction, at an overlapping position, the width X2 of the second non-power generation area of an upper curved solar panel is smaller than the width X1 of the first non-power generation area of a lower curved solar panel. In this way, it is beneficial to ensure that for two adjacent curved solar panels in the first direction, the power generation area of the lower curved solar panel cannot be blocked by the upper curved solar panel, facilitating the improvement of an overall power generation efficiency of the solar energy system using the curved solar panel.

In some embodiments, the first non-power generation area is located at the trough portion. The second non-power generation area is located at the crest portion.

A second aspect of the present disclosure provides a photovoltaic array. The photovoltaic array includes a plurality of curved solar panels provided in the first aspect of the present disclosure. In the first direction, the upper part of the first non-power generation area of each of the plurality of curved solar panels overlaps with the second non-power generation area of an adjacent one of the plurality of curved solar panels to form a first overlapping portion. An overlapping width of the first overlapping portion of any two adjacent curved solar panels of the plurality of curved solar panels in the first direction is defined as W1, where W1, X1, and X2 satisfy: W1≥(X1+X2)/2.

The photovoltaic array in the second aspect of the present disclosure has at least the same advantages as the curved solar panel in the first aspect. Moreover, W1, X1, and X2 satisfy: W1≥(X1+X2)/2, which facilitates to ensure that the power generation layers at both ends of the curved solar panel in the first direction are not blocked.

In some embodiments, each of the plurality of curved solar panels further includes a third non-power generation area and a fourth non-power generation area that are located at two opposite sides of the power generation area in a second direction different from the first direction, respectively. The first non-power generation area, the third non-power generation area, the second non-power generation area, and the fourth non-power generation area are sequentially connected and surround the power generation area. In the second direction, an upper part of the third non-power generation area of each of the plurality of curved solar panels overlaps with the fourth non-power generation area of an adjacent one of the plurality of curved solar panels to form a second overlapping portion. An overlapping width of the second overlapping portion of any two adjacent curved solar panels of the plurality of curved solar panels in the second direction is defined as H1. A width of the third non-power generation area in the second direction is defined as X3, where H1, X3, and W satisfy: H1≤X3+W.

In some embodiments, a standard angle between the photovoltaic array and a horizontal surface is defined as θ; and an actual angle between each of the plurality of curved solar panels and the horizontal surface is defined as θ1, where θ1 and θ satisfy: |θ1−θ|≤1°.

In some embodiments, the photovoltaic array further includes a plurality of voltage-current adjustment units. Each of the plurality of voltage-current adjustment units is connected in series with a corresponding curved solar panel of the plurality of curved solar panels.

In some embodiments, the plurality of curved solar panels oriented in the same direction are connected in series. The plurality of curved solar panels oriented in different directions are connected in parallel.

In some embodiments, the photovoltaic array further includes a positive combiner box and a negative combiner box. A positive electrode of each of the plurality of curved solar panels is electrically connected to the positive combiner box. A negative electrode of each of the plurality of curved solar panels is electrically connected to the negative combiner box.

A third aspect of the present disclosure provides a solar energy system. The solar energy system includes an energy storage device and the photovoltaic array in the second aspect of the present disclosure. The photovoltaic array is electrically connected to the energy storage device for supplying electric energy to the energy storage device.

The solar energy system in the third aspect of the present disclosure has at least the same advantages as the photovoltaic array in the second aspect of the present disclosure.

In some embodiments, the solar energy system further includes a controller having an end electrically connected to the photovoltaic array and another end electrically connected to each of the energy storage device and a power grid. The controller is configured to control the photovoltaic array to supply the electric energy to the energy storage device and/or the power grid.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic view of a solar energy system according to a first embodiment of the present disclosure.

FIG. 2 is a schematic view of a mounting surface of a curved solar panel in a solar energy system according to an embodiment of the present disclosure.

FIG. 3 is a side view of a curved solar panel according to an embodiment of the present disclosure.

FIG. 4 is a schematic view of curved solar panels overlapped in a first direction according to an embodiment of the present disclosure.

FIG. 5 is a schematic view of an actual angle between a curved solar panel and a horizontal surface according to an embodiment of the present disclosure.

FIG. 6 is a perspective view of a curved solar panel according to an embodiment of the present disclosure.

FIG. 7 is a schematic view of curved solar panels overlapped in a second direction according to an embodiment of the present disclosure.

FIG. 8 is a schematic view showing an application scenario of a solar energy system according to a second embodiment of the present disclosure.

### DESCRIPTION OF REFERENCE SYMBOLS OF MAIN COMPONENTS

| | |
|---|---|
| solar energy system | 100a, 100b |
| photovoltaic array | 10 |
| first photovoltaic module | 10a |
| second photovoltaic module | 10b |
| curved solar panel | 11 |
| front panel | 111 |
| back panel | 112 |
| power generation layer | 113 |
| first non-power generation area | 11a |
| second non-power generation area | 11b |
| third non-power generation area | 11c |
| fourth non-power generation area | 11d |
| power generation area | 11e |
| light receiving surface | 11f |
| backlight surface | 11g |
| trough portion | 11r |
| crest portion | 11p |
| voltage-current adjustment unit | 12 |
| positive combiner box | 13 |
| negative combiner box | 14 |
| energy storage device | 20 |
| controller | 30 |
| power grid | 200 |
| first direction | D1 |
| second direction | D2 |
| third direction | D3 |
| mounting surface | S |
| first mounting surface | S1 |
| second mounting surface | S2 |
| third mounting surface | S3 |
| fourth mounting surface | S4 |
| horizontal surface | HS |
| virtual surface | VS |
| sunlight | L |

### DETAILED DESCRIPTION OF THE EMBODIMENTS

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative only, and are intended to explain, rather than limit, the present disclosure.

A number of embodiments or examples are provided in the following disclosure of the present disclosure to implement different structures of the embodiments of the present disclosure. To simplify the disclosure of the embodiments of the present disclosure, components and arrangements of particular examples will be described below, which are, of course, examples only and are not intended to limit the present disclosure. Further, reference numerals and/or reference letters may be repeated in different examples of the embodiments of the present disclosure. Such repetition is for the purpose of simplicity and clarity and does not indicate any relationship between various embodiments and/or arrangements in question. In addition, various examples of specific processes and materials are provided in the embodiments of the present disclosure. However, those of ordinary skill in the art may be aware of applications of other processes and/or the use of other materials.

Since a backlight surface of the curved solar panel is an uneven curved surface, when mounted on a roof, it is difficult to ensure that an overlapping area between each curved solar panel and an adjacent curved solar panel is consistent, allowing an actual power generation area of each curved solar panel to be different. Therefore, when there is a predetermined angle between the sunlight and a plane irradiation angle of the curved solar panel as a sunshine duration changes, the power generation capacity of each curved solar panel varies greatly, ultimately leading to a decrease in the overall power generation efficiency of an entire solar energy system due to current limiting.

In the embodiments of the present disclosure, “current limiting” refers to controlling the flow of current by electrical means to protect components in the solar energy system, improve efficiency, and maintain the stability of the solar energy system. Specifically, in the solar energy system, when the power generation efficiency of a predetermined solar panel in a plurality of solar panels connected in series decreases and an output current is reduced, an overall output current of the entire solar energy system decreases to prevent other components (such as an inverter and a controller) in the solar energy system from being damaged due to excessive current.

Technical solutions according to embodiments of the present disclosure will be described clearly and completely below in combination with accompanying drawings of the embodiments of the present disclosure. Obviously, the embodiments described below are only a part of the embodiments of the present disclosure, rather than all embodiments of the present disclosure.

As illustrated in FIG. 1, a solar energy system 100a according to a first embodiment of the present disclosure includes a photovoltaic array 10 and an energy storage device 20 electrically connected to the photovoltaic array 10. The photovoltaic array 10 is configured to supply electric energy to the energy storage device 20. The energy storage device 20 can store the electric energy generated by the photovoltaic array 10 during the day for use at night or when the photovoltaic array 10 does not generate electricity. The energy storage device 20 is, for example, a lithium-ion battery, but is not limited thereto.

Specifically, the photovoltaic array 10 includes a first photovoltaic module 10a, a second photovoltaic module 10b, a positive combiner box 13, and a negative combiner box 14. The first photovoltaic module 10a includes a plurality of curved solar panels 11 and a plurality of voltage-current adjustment units 12. In the first photovoltaic module 10a, the number of curved solar panels 11 is the same as that of voltage-current adjustment units 12. Each of the plurality of voltage-current adjustment units 12 is connected in series with a corresponding curved solar panel 11, and the plurality of voltage-current adjustment units 12 are connected in series with each other. In the first photovoltaic module 10a, a positive electrode of each of the plurality of curved solar panels 11 and a positive electrode of each of the plurality of voltage-current adjustment units 12 are electrically connected to the positive combiner box 13, and a negative electrode of each of the plurality of curved solar panels 11 and a negative electrode of each of the plurality of voltage-current adjustment units 12 are electrically connected to the negative combiner box 14.

The second photovoltaic module 10b has the same composition as the first photovoltaic module 10a. The second photovoltaic module 10b includes the plurality of curved solar panels 11 and the plurality of voltage-current adjustment units 12. In the second photovoltaic module 10b, the number of curved solar panels 11 is the same as that of voltage-current adjustment units 12. Each of the plurality of voltage-current adjustment units 12 is connected in series with a corresponding curved solar panel 11, and the plurality of voltage-current adjustment units 12 are connected in series with each other. In the second photovoltaic module 10b, the positive electrode of each of the plurality of curved solar panels 11 and the positive electrode of each of the plurality of voltage-current adjustment units 12 are electrically connected to the positive combiner box 13, and the negative electrode of each of the plurality of curved solar panels 11 and the negative electrode of each of the plurality of voltage-current adjustment units 12 are electrically connected to the negative combiner box 14.

In some embodiments, the voltage-current adjustment unit 12 includes an electric charge controller. The electric charge controller has a function of regulating a voltage and a current of the curved solar panel 11 connected in parallel with the electric charge controller to prevent overcharging and over-discharging. In addition, the electric charge controller also has a function of preventing a current in the energy storage device 20 from flowing back to the curved solar panel 11 at night or when light is insufficient. Further, the electric charge controller may also adopt maximum power point tracking technology to optimize conversion of electric energy from the curved solar panel 11 to the energy storage device 20. The arrangement of the above positive combiner box 13 and negative combiner

box 14 allows current (DC) input lines of the plurality of curved solar panels 11 in the photovoltaic array 10 to be collected together and the current to be transmitted to the energy storage device 20 through a single line. In this way, wiring can be simplified, which reduces the complexity of wire connections, simplifying mounting and maintenance of the solar energy system 100a. In addition, fuses or circuit breakers may also be disposed in the positive combiner box 13 and the negative combiner box 14 to prevent overcurrent situations. If a problem occurs in a predetermined circuit, the corresponding fuse blows, protecting the entire solar energy system 100a from damage. Moreover, the positive combiner box 13 and the negative combiner box 14 also have waterproof and dustproof functions, which can protect internal electrical components from adverse environmental conditions, enhancing safety of the system.

In some embodiments, all the plurality of curved solar panels 11 in the first photovoltaic module 10a are oriented in the same direction, and all the plurality of curved solar panels 11 in the second photovoltaic module 10b are oriented in the same direction. However, the plurality of curved solar panels 11 in the first photovoltaic module 10a and the plurality of curved solar panels 11 in the second photovoltaic module 10b are oriented in different directions. That is, the curved solar panels 11 in the same photovoltaic module are connected in series and oriented in the same direction, while the curved solar panels 11 in different photovoltaic modules are connected in parallel and oriented in different directions. The above directions may be any one of east, west, south, north, southeast, northeast, southwest, northwest and other orientations.

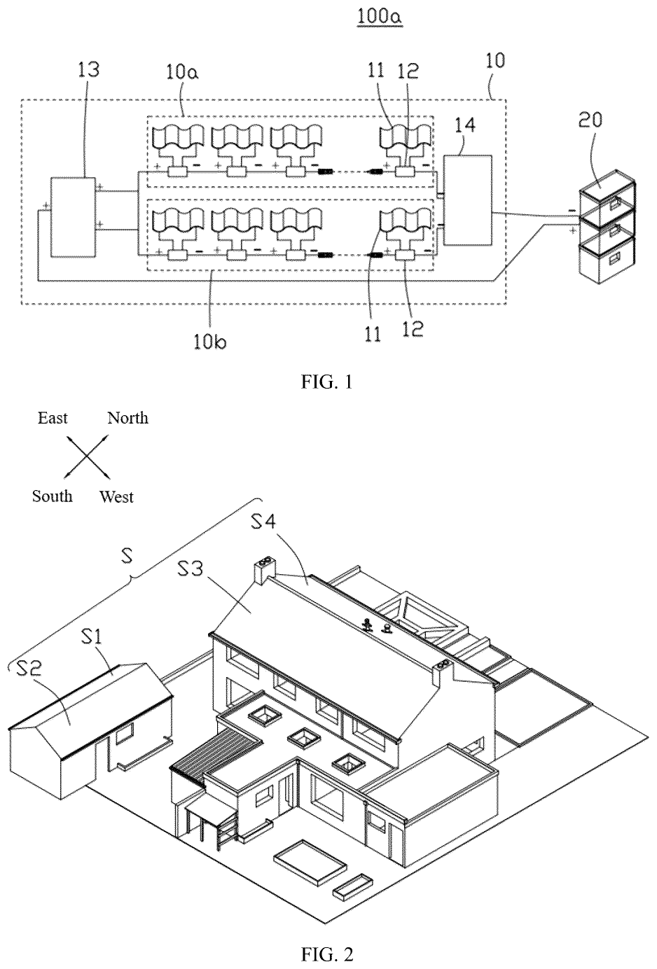

As illustrated in FIG. 2, the solar energy system 100a is applied to a household power supply scenario. Mounting surfaces S on the roof of the building includes a first mounting surface S1 facing east, a second mounting surface S2 facing west, a third mounting surface S3 facing south, and a fourth mounting surface S4 facing north. The above first photovoltaic module 10a and second photovoltaic module 10b may be mounted at any two different ones of the above four mounting surfaces S. In the embodiments illustrated in FIG. 1, the photovoltaic array 10 includes two groups of photovoltaic modules as an example. In other embodiments, the number of photovoltaic modules in the photovoltaic array 10 is not limited to the above.

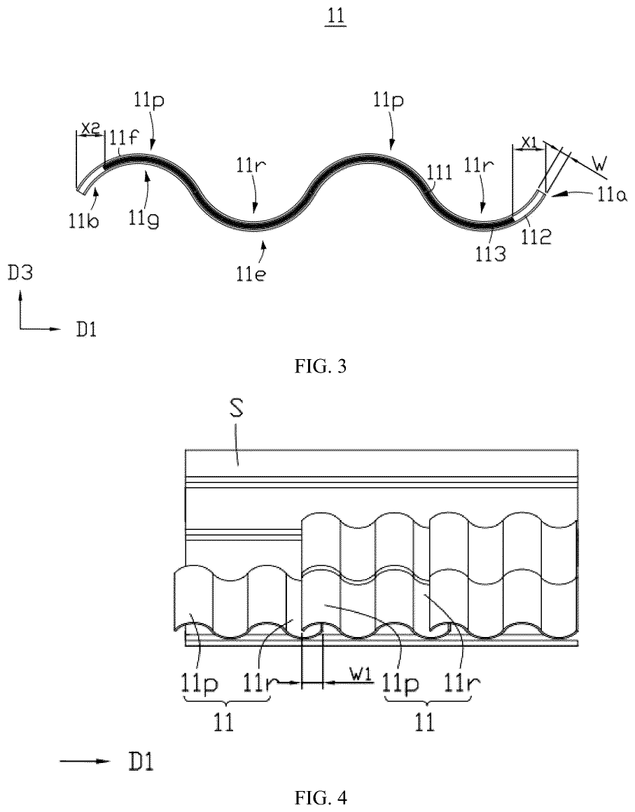

As illustrated in FIG. 3, the curved solar panel 11 includes a crest portion 11p and a trough portion 11r that are sequentially connected in a first direction D1. Specifically, the curved solar panel 11 includes a front panel 111, a back panel 112, and a power generation layer 113 sandwiched between the front panel 111 and the back panel 112. The back panel 112, the power generation layer 113, and the front panel 111 are stacked in sequence in a third direction D3. The first direction D1 is perpendicular to the third direction D3.

For the convenience of description, the first direction D1 is also referred to as a left-right direction, and the third direction D3 is referred to as an up-down direction. A direction from a negative direction of the first direction D1 to a positive direction of the first direction D1 is from left to right. A direction from a negative direction of the third direction D3 to a positive direction of the third direction D3 is from bottom to top.

More specifically, the curved solar panel 11 includes a light receiving surface 11f and a backlight surface 11g that are opposite to each other. A side of the curved solar panel 11 where the light receiving surface 11f is located is used to receive sunlight L. The front panel 111 is located at the side of the curved solar panel 11 where the light receiving surface 11f is located to protect the light receiving surface 11f of the power generation layer 113. The front panel 111 is, for example, light-transmitting curved glass, but is not limited thereto. The back panel 112 is located at a side of the curved solar panel 11 where the backlight surface 11g is located to support and protect a side of the backlight surface 11g of the power generation layer 113. The back panel 112 is, for example, a flexible back panel or curved glass, but is not limited thereto. The power generation layer 113 includes a plurality of solar cells electrically connected to each other. The curved solar panel 11 further includes an encapsulant film between the front panel 111 and the power generation layer 113 and an encapsulant film between the back panel 112 and the power generation layer 113, but is not limited thereto.

The curved solar panel 11 includes a power generation area 11e and a non-power generation area. The power generation area 11e is provided with the power generation layer 113, and the non-power generation area is not provided with the power generation layer 113. Specifically, the non-power generation area includes a first non-power generation area 11a and a second non-power generation area 11b. The first non-power generation area 11a and the second non-power generation area 11b are located at two opposite sides of the power generation area 11e in the first direction D1, respectively. When the curved solar panel 11 is mounted, in the first direction D1, an upper part of the first non-power generation area 11a of each of the plurality of curved solar panels 11 is configured to overlap with the second non-power generation area 11b of an adjacent curved solar panel 11 of the plurality of curved solar panels 11.

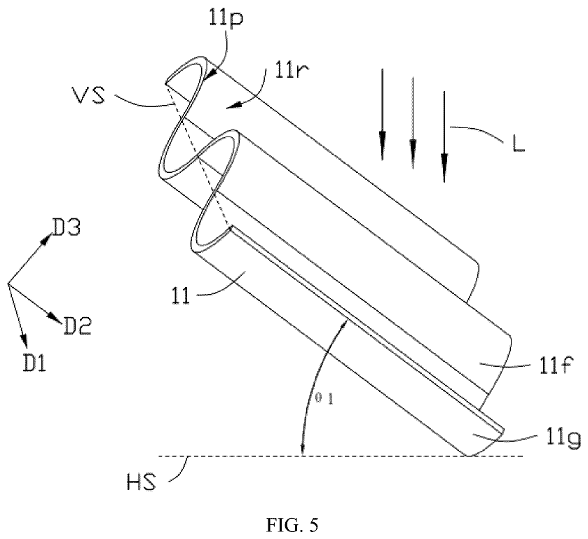

A width of the first non-power generation area 11a in the first direction D1 is X1. A width of the second non-power generation area 11b in the first direction D1 is X2. A thickness of the curved solar panel 11 is W, where X1, X2, and W satisfy: X1≥X2+W. In this way, as illustrated in FIG. 4, when the plurality of curved solar panels 11 according to the embodiments of the present disclosure are mounted in order from left to right, at an overlapping position, the width X2 of the second non-power generation area 11b of the upper curved solar panel 11 is smaller than the width X1 of the first non-power generation area 11a of the lower curved solar panel 11, facilitating to ensure that in two adjacent curved solar panels 11 in the first direction D1, the power generation layer 113 of the curved solar panel 11 on the left cannot be blocked by the curved solar panel 11 on the right, avoiding impacts on overall power generation efficiency.

Further, the upper part of the first non-power generation area 11a of each of the plurality of curved solar panels 11 overlaps with the second non-power generation area 11b of an adjacent one of the plurality of curved solar panels 11 to form a first overlapping portion. An overlapping width of the first overlapping portion of any two adjacent curved solar panels 11 of the plurality of curved solar panels 11 in the first direction D1 is defined as W1, where W1, X1, and X2 satisfy: W1≥(X1+X2)/2. In this way, it is beneficial to ensure that the power generation layers 113 at both ends of each of the plurality of curved solar panels 11 in the first direction D1 are not be blocked during overlapping in the first direction D1.

In the embodiments as illustrated in FIG. 3 and FIG. 4, each of the plurality of curved solar panels 11 includes two crest portions 11p and two trough portions 11r. Each of the two crest portions 11p is alternately connected to one trough portion 11r in sequence in the first direction D1. Among both ends of each of the plurality of curved solar panels 11 along the first direction D1, one end is the crest portion 11p and the other end is the trough portion 11r. The first non-power generation area 11a is located at a through-shaped end of the curved solar panel 11, and the second non power generation area 11b is located at a crest-shaped end of the curved solar panel 11. In other words, the first non-power generation area 11a is located at the trough portion 11r of the curved solar panel 11, and the second non-power generation area 11b is located at the crest portion 11p of the curved solar panel 11. In this way, two adjacent curved solar panels 11 are fitted and overlapped with each other in the left-right direction, which is beneficial to improving overall structural stability, avoiding displacement or damage caused by environmental factors (such as wind and rain).

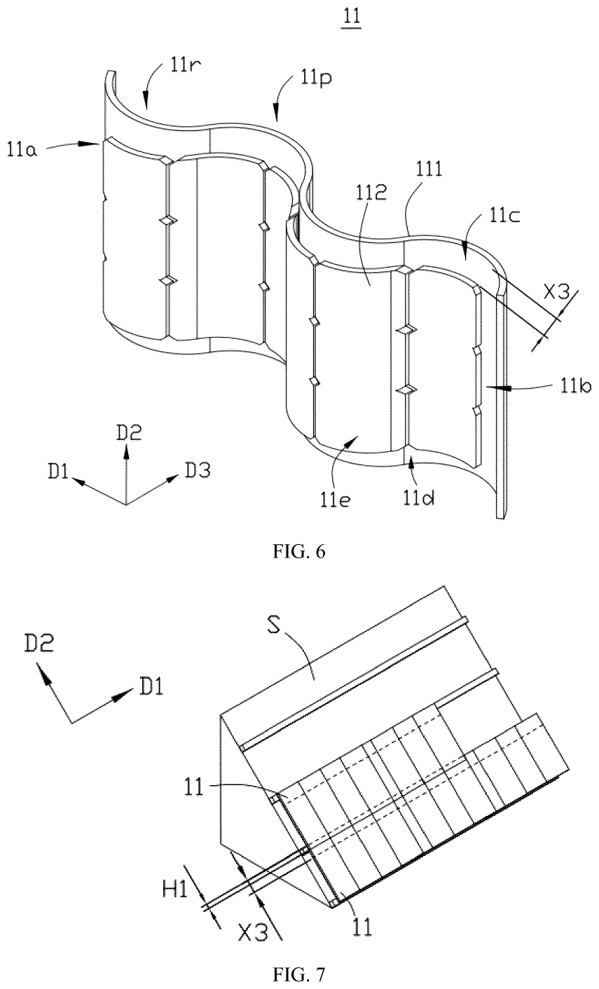

In some embodiments, to ensure that actual power-generation power of different curved solar panels 11 is consistent, it is also necessary to ensure that an inclination angle of each curved solar panel 11 is the same. Specifically, the actual power-generation power P=voltage V×current I=irradiation HA×light receiving area S×conversion efficiency K1×system efficiency K. As illustrated in FIG. 5, for a case where the sunlight Lis incident on the curved solar panel 11 perpendicularly to a horizontal surface HS, a standard angle between the photovoltaic array 10 and the horizontal surface HS is θ, and an actual angle between the curved solar panel 11 and the horizontal surface HS is θ1. Then, a difference in light receiving area between the curved solar panel 11 and a standard curved solar panel is |cos θ1−cos θ|×S. Therefore, the difference in the light receiving area becomes greater and a difference in power-generation power becomes greater as a difference between the actual angle between the curved solar panel 11 and the horizontal surface HS and the standard angle between the curved solar panel 11 and the horizontal surface HS increases.

In some embodiments, after each of the plurality of curved solar panels 11 is mounted, a level is used to determine whether the difference between the actual angle between the curved solar panel 11 and the horizontal surface HS and the standard angle between the curved solar panel 11 and the horizontal surface HS satisfies |θ1−θ|≤1°, but the present disclosure is not limited thereto.

It should be noted that, the above standard angle is a specified angle of the photovoltaic array 10, and this specified angle is a designed constant value. In addition, the horizontal surface HS is a theoretical reference plane and is an equipotential plane of the earth's gravity field. On the horizontal surface HS, gravitational potential energy of any two points is equal, which means that theoretically, water does not flow on this surface.

In addition, the horizontal surface HS shown in FIG. 5 is only for illustration. It should be understood that, since the earth's gravity field is affected by uneven distribution of its own mass, the horizontal surface HS is not a completely flat surface.

In the embodiments illustrated in FIG. 5, each crest portion 11p and each trough portion 11r extend in a second direction D2. The first direction D1, the second direction D2, and the third direction D3 are mutually perpendicular. Cross-sections of each crest portion 11p and each trough portion 11r that are perpendicular to the second direction D2 are both semicircular. A plane where a center of the semicircle of each of the crest portion 11p and the trough portion 11r is located forms a virtual surface VS parallel to a plane formed by the first direction D1 and the second direction D2. The actual angle between the above curved solar panel 11 and the horizontal surface HS is an angle between the virtual surface VS and the horizontal surface HS.

As illustrated in FIG. 6, the curved solar panel 11 further includes a third non-power generation area 11c and a fourth non-power generation area 11d that are located at two opposite sides of the power generation area 11e in the second direction D2, respectively. The first non-power generation area 11a, the third non-power generation area 11c, the second non-power generation area 11b, and the fourth non-power generation area 11d are sequentially connected and surround the power generation area 11e. In the second direction D2, an upper part of the third non-power generation area 11c of the curved solar panel 11 overlaps with the fourth non-power generation area 11d of an adjacent curved solar panel 11. It should be noted that, for the convenience of description, the back panel 112 is omitted in FIG. 6.

As illustrated in FIG. 7, when the plurality of curved solar panels 11 are mounted at the mounting surface S of the roof, each row of curved solar panels 11 is mounted in order from left to right in the first direction D1, and multiple rows of curved solar panels 11 are mounted row by row in order from bottom to top in the second direction D2. That is, after a lower row of curved solar panels 11 is mounted, an upper row of curved solar panels 11 is mounted.

Specifically, an upper part of the third non-power generation area 11c of each of the plurality of curved solar panels 11 overlaps with the fourth non-power generation area 11d of an adjacent one of the plurality of curved solar panels 11 to form a second overlapping portion. An overlapping width of the second overlapping portion of any two adjacent curved solar panels 11 of the plurality of curved solar panels 11 in the second direction D2 is defined as H1, and a width of the third non-power generation area 11c in the second direction D2 is X3, where H1, X3, and the thickness W of the curved solar panel 11 satisfy: H1≤X3+W. In this way, it is beneficial to ensure that when two adjacent curved solar panels 11 are overlapped in the second direction D2, the power generation layer 113 of the lower curved solar panel 11 cannot be blocked or shaded by the upper curved solar panel 11, avoiding impacts on the power generation efficiency of the entire solar energy system 100a. In addition, it is also beneficial to avoid a situation where the encapsulant film dissolves and delaminates due to local overheating caused by the hot spot effect in a predetermined curved solar panel 11.

The mounting principles of the solar energy system 100a according to the embodiments of the present disclosure are specifically described as follows.

First, all curved solar panels 11 on the same mounting surface S are mounted in series, and all curved solar panels 11 on different mounting surfaces S are mounted in parallel.

Second, each row of curved solar panels 11 is mounted in the order from left to right in the first direction D1; and multiple rows of curved solar panels 11 are mounted in the order from bottom to top in the second direction D2.

Third, when mounted from left to right, in the first direction D1, the overlapping width W1 of the overlapping portion of any two adjacent curved solar panels 11 of the plurality of curved solar panels, the width X1 of the first non-power generation area 11a, and the width X2 of the second non-power generation area 11b need to satisfy: W1≥(X1+X2)/2, to ensure that during overlapping from left to right, the power generation layer 113 cannot be overlapped, preventing shading on the solar cells and avoiding impacts on the power generation efficiency. In addition, since the curved solar panel is curved, it is difficult to ensure that the width of the first non-power generation area 11a is equal to the width of the second non-power generation area 11b during design. When following the left-to-right mounting principle, if the width of the first non-power generation area 11a is smaller than or equal to the width of the second non-power generation area 11b, the power generation layer 113 is also blocked. Therefore, it is necessary to further satisfy X1≥X2+W to ensure that solar cells of the curved solar panel 11 on the left are not blocked.

Fourth, after a curved solar panel 11 is mounted, a level is used to determine whether the difference between the actual angle between the curved solar panel 11 and the horizontal surface HS and the standard angle between the curved solar panel 11 and the horizontal surface HS satisfies |θ1−θ|≤1°. If not, the angle of the curved solar panel 11 needs to be adjusted until the requirement is met.

Fifth, in the second direction D2, the overlapping width H1 of the overlapping portion of two adjacent curved solar panels 11 of the plurality of curved solar panels 11, the width X3 of the third non-power generation area 11c, and the thickness W of the curved solar panel 11 satisfy: H1≤X3+W. Otherwise, the position needs to be adjusted to ensure that solar cells of the lower curved solar panel 11 cannot be blocked or shaded during top-bottom overlapping, avoiding impacts on the power-generation power. Also, it is beneficial to avoid a situation where the encapsulant film dissolves and delaminates due to local overheating caused by the hot spot effect in a predetermined curved solar panel 11.

Sixth, after the curved solar panel 11 is mounted, a circuit is connected as desired according to FIG. 1. When the circuit is connected, the power generation area 11e of the curved solar panel 11 needs to be blocked to prevent the risk of electric shock.

In summary, the solar energy system according to the embodiments of the present disclosure, by designing sizes of the non-power generation areas of the curved solar panels and thicknesses of the curved solar panels, is conducive to solving a problem that the overall power generation efficiency of the solar energy system is affected due to local blocking during overlapping of the curved solar panels. In some embodiments, by setting of the above mounting principles and in cooperation with the voltage-current adjustment unit, the system efficiency of the curved solar panels mounted at the roof can be effectively improved by about 30%.

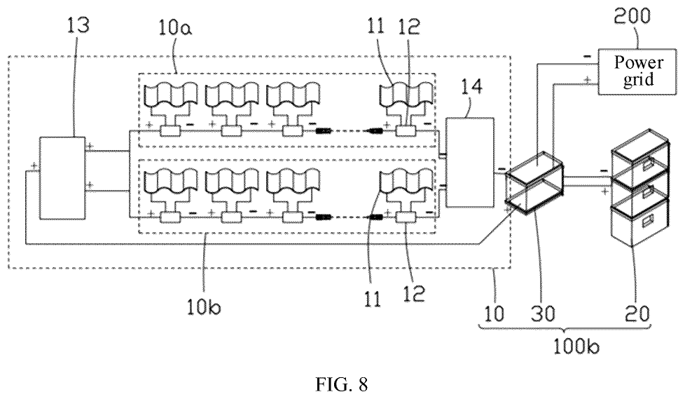

As illustrated in FIG. 8, a difference between a solar energy system 100b according to a second embodiment of the present disclosure and the solar energy system 100a according to the first embodiment is that: the solar energy system 100b further includes a controller 30 having an end electrically connected to the photovoltaic array 10 and another end electrically connected to each of the energy storage device 20 and a power grid 200. The controller 30 is configured to control the photovoltaic array 10 to supply the electric energy to the energy storage device 20 and/or the power grid 200.

It should be understood that, the above mounting principles of the solar energy system 100a are also applicable to the solar energy system 100b.

Specifically, the solar energy system 100a is an off-grid system capable of self-generation and automatic operation. That is, the solar energy system 100a can operate independently without being connected to the public power grid 200. In addition, the solar energy system 100a can automatically manage power generation and power storage processes without manual intervention. For example, when the electric energy generated by the curved solar panel 11 in the photovoltaic array 10 exceeds current household consumption, the solar energy system 100a can automatically store surplus electric energy in the energy storage device 20. When the electric energy generated by the curved solar panel 11 in the photovoltaic array 10 is insufficient to meet the demand, the solar energy system 100a can automatically draw electricity from the energy storage device 20 for household use.

In addition, the solar energy system 100b is a grid-connected system. The solar energy system 100b is not only capable of self-generation and automatic operation, but also able to feed surplus electricity to the grid. That is, in addition to satisfying self-sufficiency of household loads, the solar energy system 100b can also transmit surplus electric energy to the public power grid 200, giving it the possibility to contribute the electric energy to the power grid 200.

Reference throughout this specification to “an embodiment”, “some embodiments”, “an illustrative embodiment”, “an example”, “a specific example”, or “some examples” means that a particular feature, structure, material, or characteristic described in connection with the embodiment or example is included in at least one embodiment or example of the present disclosure. The appearances of the above phrases in various places throughout this specification are not necessarily referring to the same embodiment or example. Further, the particular features, structures, materials, or characteristics may be combined in any suitable manner in one or more embodiments or examples.

Although embodiments of the present disclosure have been illustrated and described, it is conceivable for those skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A curved solar panel, comprising a crest portion and a trough portion that are sequentially connected in a first direction, wherein the curved solar panel further comprises:
a power generation area provided with a power generation layer; and
a first non-power generation area and a second non-power generation area that are located at two opposite sides of the power generation area in the first direction, respectively, an upper part of the first non-power generation area being configured to overlap with the second non-power generation area of an adjacent curved solar panel, wherein:
a width of the first non-power generation area in the first direction is defined as X1;
a width of the second non-power generation area in the first direction is defined as X2; and
a thickness of the curved solar panel is defined as W, where X1, X2, and W satisfy:
$$X 1 \geq X 2 + W .$$

2. The curved solar panel according to claim 1, wherein:
the first non-power generation area is located at the trough portion; and
the second non-power generation area is located at the crest portion.

3. The curved solar panel according to claim 1, further comprising:
a front panel and a back panel, the power generation layer being sandwiched between the front panel and the back panel, and the back panel, the power generation layer, and the front panel being stacked in sequence.

4. A photovoltaic array, comprising:
a plurality of curved solar panels, each of the plurality of curved solar panels comprising a crest portion and a trough portion that are sequentially connected in a first direction,
wherein each of the plurality of curved solar panels further comprises:
a power generation area provided with a power generation layer; and
a first non-power generation area and a second non-power generation area that are located at two opposite sides of the power generation area in the first direction, respectively, an upper part of the first non-power generation area being configured to overlap with the second non-power generation area of an adjacent curved solar panel, wherein:
a width of the first non-power generation area in the first direction is defined as X1;
a width of the second non-power generation area in the first direction is defined as X2; and
a thickness of the curved solar panel is defined as W, where X1, X2, and W satisfy:
$$X 1 \geq X 2 + W ;$$
wherein in the first direction, the upper part of the first non-power generation area of each of the plurality of curved solar panels overlaps with the second non-power generation area of an adjacent one of the plurality of curved solar panels to form a first overlapping portion; and
wherein an overlapping width of the first overlapping portion of any two adjacent curved solar panels of the plurality of curved solar panels in the first direction is defined as W1, where W1, X1, and X2 satisfy: W1≥(X1+X2)/2.

5. The photovoltaic array according to claim 4, wherein:
each of the plurality of curved solar panels further comprises a third non-power generation area and a fourth non-power generation area that are located at two opposite sides of the power generation area in a second direction different from the first direction, respectively, the first non-power generation area, the third non-power generation area, the second non-power generation area, and the fourth non-power generation area being sequentially connected and surrounding the power generation area;
in the second direction, an upper part of the third non-power generation area of each of the plurality of curved solar panels overlaps with the fourth non-power generation area of an adjacent one of the plurality of curved solar panels to form a second overlapping portion;
an overlapping width of the second overlapping portion of any two adjacent curved solar panels of the plurality of curved solar panels in the second direction is defined as H1;
a width of the third non-power generation area in the second direction is defined as X3, where H1, X3, and W satisfy: H1≤X3+W.

6. The photovoltaic array according to claim 5, wherein:
a standard angle between the photovoltaic array and a horizontal surface is defined as θ; and
an actual angle between each of the plurality of curved solar panels and the horizontal surface is defined as θ1, where θ1 and θ satisfy: |θ1−θ|≤1°.

7. The photovoltaic array according to claim 4, further comprising:
a plurality of voltage-current adjustment units, each of the plurality of voltage-current adjustment units being connected in series with a corresponding curved solar panel of the plurality of curved solar panels.

8. The photovoltaic array according to claim 7, wherein:
the plurality of curved solar panels oriented in the same direction are connected in series; and
the plurality of curved solar panels oriented in different directions are connected in parallel.

9. The photovoltaic array according to claim 7, further comprising:
a positive combiner box and a negative combiner box, a positive electrode of each of the plurality of curved solar panels being electrically connected to the positive combiner box, and a negative electrode of each of the plurality of curved solar panels being electrically connected to the negative combiner box.

10. The photovoltaic array according to claim 4, wherein:
the first non-power generation area is located at the trough portion; and
the second non-power generation area is located at the crest portion.

11. The photovoltaic array according to claim 4, wherein each of the plurality of curved solar panels further comprises a front panel and a back panel, the power generation layer being sandwiched between the front panel and the back panel, and the back panel, the power generation layer, and the front panel being stacked in sequence.

12. A solar energy system, comprising:
an energy storage device; and
the photovoltaic array according to claim 4, the photovoltaic array being electrically connected to the energy storage device for supplying electric energy to the energy storage device.

13. The solar energy system according to claim 12, further comprising:
a controller having an end electrically connected to the photovoltaic array and another end electrically connected to each of the energy storage device and a power grid, the controller being configured to control the photovoltaic array to supply the electric energy to the energy storage device and/or the power grid.

14. The solar energy system according to claim 12, wherein:
each of the plurality of curved solar panels further comprises a third non-power generation area and a fourth non-power generation area that are located at two opposite sides of the power generation area in a second direction different from the first direction, respectively, the first non-power generation area, the third non-power generation area, the second non-power generation area, and the fourth non-power generation area being sequentially connected and surrounding the power generation area;
in the second direction, an upper part of the third non-power generation area of each of the plurality of curved solar panels overlaps with the fourth non-power generation area of an adjacent one of the plurality of curved solar panels to form a second overlapping portion;
an overlapping width of the second overlapping portion of any two adjacent curved solar panels of the plurality of curved solar panels in the second direction is defined as H1;
a width of the third non-power generation area in the second direction is defined as X3, where H1, X3, and W satisfy: H1≤X3+W.

15. The solar energy system according to claim 14, wherein:
a standard angle between the photovoltaic array and a horizontal surface is defined as θ; and
an actual angle between each of the plurality of curved solar panels and the horizontal surface is defined as θ1, where θ1 and θ satisfy: |θ1−θ|≤1°.

16. The solar energy system according to claim 12, wherein the photovoltaic array further comprises a plurality of voltage-current adjustment units, each of the plurality of voltage-current adjustment units being connected in series with a corresponding curved solar panel of the plurality of curved solar panels.

17. The solar energy system according to claim 16, wherein:
the plurality of curved solar panels oriented in the same direction are connected in series; and
the plurality of curved solar panels oriented in different directions are connected in parallel.

18. The solar energy system according to claim 16, wherein the photovoltaic array further comprises a positive combiner box and a negative combiner box, a positive electrode of each of the plurality of curved solar panels being electrically connected to the positive combiner box, and a negative electrode of each of the plurality of curved solar panels being electrically connected to the negative combiner box.

19. The solar energy system according to claim 12, wherein:
the first non-power generation area is located at the trough portion; and
the second non-power generation area is located at the crest portion.

20. The solar energy system according to claim 12, wherein each of the plurality of curved solar panels further comprises a front panel and a back panel, the power generation layer being sandwiched between the front panel and the back panel, and the back panel, the power generation layer, and the front panel being stacked in sequence.
